(19) United States
(12) Patent Application Publication
(10) Pub. No.: US 2026/0004175 A1
(43) Pub. Date: Jan. 1, 2026

(54) TECHNIQUES FOR PERFORMING ENTANGLING GATES ON LOGICAL QUBITS AND RELATED SYSTEMS AND METHODS

(71) Applicant: Yale University, New Haven, CT (US)

(72) Inventors: Robert J. Schoelkopf, III, Madison, CT (US); Takahiro Tsunoda, New Haven, CT (US); James Teoh, New Haven, CT (US); Benjamin Chapman, Seattle, WA (US); Stijn de Graaf, New Haven, CT (US); William Kalfus, New Haven, CT (US); Jacob Curtis, New Haven, CT (US); Neel Thakur, New Haven, CT (US)

(73) Assignee: Yale University, New Haven, CT (US)

(21) Appl. No.: 19/116,294

(22) PCT Filed: Sep. 29, 2023
(86) PCT No.: PCT/US2023/075555

§ 371 Date: Mar. 27, 2025

Related U.S. Application Data
(60) Provisional application No. 63/411,791, filed on Sep. 30, 2022.
(60) Provisional application No. 63/433,411, filed on Dec. 16, 2022.

(51) Int. Cl. G06N 10/40; G01R 33/035

(52) U.S. Cl. CPC G06N 10/40; G01R 33/0354

(57) ABSTRACT

Techniques are described for performing two-qubit gates on logical qubits. The two-qubit gates may be performed in a manner that is fault tolerant and/or that produces an indication of whether or not an error occurred during the gate. The robustness of the described techniques against errors is provided at the hardware level by engineering a system in which an ancilla qubit acts as flag states for certain errors. As such, manipulating the state of the system to counteract an error may not be necessary; rather, when errors occur the result of a gate may be filtered out, or performed again. In other cases, the error state may simply be recorded as an indication of quality of the state of the system. The techniques for performing two-qubit gates described herein may also be compatible with different bosonic encodings of logical qubits, of which illustrative examples are described.

### GOVERNMENT FUNDING

This invention was made with government support under W911NF-18-1-0212 awarded by the United States Army Research Office. The government has certain rights in the invention.

### BACKGROUND

Quantum information processing techniques perform computation by manipulating one or more quantum objects. These techniques are sometimes referred to as “quantum computing.” In order to perform computations, a quantum information processor utilizes quantum objects to reliably store and retrieve information. According to some quantum information processing approaches, a quantum analogue to the classical computing “bit” (being equal to 1 or 0) has been developed, which is referred to as a quantum bit, or “qubit.” A qubit can be composed of any quantum system that has two distinct states (which may be thought of as 1 and 0 states), but also has the special property that the system can be placed into quantum superpositions and thereby potentially exist in both of those states at once.

### SUMMARY

In some aspects, the techniques described herein relate to a system for implementing entangling gates that operate on two logical qubits, the system including: a first quantum oscillator; a second quantum oscillator; a coupling element coupled to the first quantum oscillator and to the second quantum oscillator; an ancilla qubit coupled to the first quantum oscillator; at least one energy source; a readout resonator coupled to the ancilla qubit; and at least one controller configured to: perform an entangling gate between logical states of the first quantum oscillator and the second quantum oscillator by operating the at least one energy source to direct energy to the coupling element and/or to the ancilla qubit one or more times; measure a state of the ancilla qubit measured subsequent to performing the entangling gate; and determine whether the entangling gate produced an error based on the measured state of the ancilla qubit.

In some aspects, the techniques described herein relate to a system for implementing entangling gates that operate on two dual-rail qubits, the system including: a first dual-rail qubit including: a first quantum oscillator; a second quantum oscillator; a first coupling element coupled to the first quantum oscillator and to the second quantum oscillator; and an ancilla qubit coupled to the second quantum oscillator; a second dual-rail qubit including: a third quantum oscillator; a fourth quantum oscillator; and a second coupling element coupled to the third quantum oscillator and to the fourth quantum oscillator; a third coupling element coupled to the second quantum oscillator and to the third quantum oscillator; at least one energy source; and at least one controller configured to: perform an entangling gate between a dual-rail state of the first dual-rail qubit and a dual-rail state of the second dual-rail qubit by operating the at least one energy source to direct energy to the third coupling element and/or to the ancilla qubit one or more times; measure a state of the ancilla qubit measured subsequent to performing the entangling gate; and determine whether the entangling gate produced an error based on the measured state of the ancilla qubit.

The foregoing apparatus and method embodiments may be implemented with any suitable combination of aspects, features, and acts described above or in further detail below. These and other aspects, embodiments, and features of the present teachings can be more fully understood from the following description in conjunction with the accompanying drawings.

### BRIEF DESCRIPTION OF DRAWINGS

Various aspects and embodiments will be described with reference to the following figures. It should be appreciated that the figures are not necessarily drawn to scale. In the drawings, each identical or nearly identical component that is illustrated in various figures is represented by a like numeral. For purposes of clarity, not every component may be labeled in every drawing.

FIG. 1 depicts an illustrative suitable for practicing the techniques described herein, according to some embodiments;

FIG. 2A depicts an illustrative implementation of the system of FIG. 1 comprising microwave cavities, according to some embodiments;

FIG. 2B depicts couplings between the elements of FIG. 2A, according to some embodiments;

FIGS. 2C and 2D depict illustrative Operator Bloch Sphere trajectories for designing entangling gates for bosonic qubits, according to some embodiments;

FIGS. 3A-3D depict illustrative Operator Bloch ere trajectories for the entangling gates ZZ, SWAP and uSWAP, according to some embodiments;

FIG. 4A is an illustrative circuit for applying error-detected bosonic entangling gates, according to some embodiments;

FIGS. 4B-4D are illustrative circuits for applying ZZ, eSWAP and Z gates, according to some embodiments;

FIG. 5A depicts a circuit for parameterizing general excitation-preserving two-qubit gates, according to some embodiments;

FIGS. 5B-5D depict illustrative instances of the circuit of FIG. 5A, according to some embodiments;

FIG. 6A depicts an illustrative implementation of the system of FIG. 1 comprising two dual-rail logical qubits implemented with microwave cavities, according to some embodiments;

FIG. 6B depicts couplings between the elements of FIG. 6A, according to some embodiments; and

FIG. 7 depicts an illustrative circuit for applying a ZZ gate for the dual-rail qubits of FIG. 6A, according to some embodiments.

### DETAILED DESCRIPTION

Quantum multi-level systems such as superconducting qubits exhibit quantum states that, based on current experimental practices, decohere in around ˜ 100 μs. While experimental techniques will undoubtedly improve on this and produce qubits with longer decoherence times, it may nonetheless be beneficial to couple a multi-level system to another system that exhibits much longer decoherence times. A system configured with bosonic modes may be particularly desirable for coupling to a multi-level system. Through this coupling, the multi-level system's state may be represented by the bosonic mode(s) instead, thereby maintaining the same information yet in a longer-lived state than would otherwise exist in the multi-level system alone. When used in this manner, the bosonic system is sometimes referred to as a “logical” qubit.

Quantum information stored in bosonic modes may nonetheless still have a limited lifetime, such that errors will still occur within the bosonic system. It may therefore be desirable to manipulate a bosonic system when errors in its state occur to effectively correct those errors and thereby regain the prior state of the system. If a broad class of errors can be corrected for, it may be possible to maintain the state of the bosonic system indefinitely (or at least for long periods of time) by correcting for any type of error that might occur.

The fields of cavity quantum electrodynamics (QED) and circuit QED (cQED) represent one illustrative experimental approach to implement quantum error correction. In these approaches, one or more qubit systems are each coupled to a resonator cavity in such a way as to allow mapping of the quantum information contained in the qubit(s) to and/or from the resonator(s). The resonator(s) generally will have a longer stable lifetime than the qubit(s). The quantum state may later be retrieved in a qubit by mapping the state back from a respective resonator to the qubit. When a multi-level system, such as a qubit, is mapped onto the state of a bosonic system to which it is coupled, a particular way to encode the qubit state in the states of the bosonic system must be selected. This choice of encoding is often referred to as a “code.”

While the use of logical qubits to store quantum information has the potential to reduce the hardware needed to perform quantum error correction, the resonators used as logical qubits must generally be engineered to have high quality factors, and operations on the logical qubits (e.g., error-correcting operations or algorithmic operations) should ideally be insensitive to errors. The latter requirement is sometimes referred to as a requirement to be “fault tolerant.”

The inventors have recognized and appreciated techniques for performing two-qubit gates on logical qubits. The two-qubit gates may be performed in a manner that is fault tolerant and/or that produces an indication of whether or not an error occurred during the gate. The robustness of the described techniques against errors is provided at the hardware level by engineering a system in which an ancilla qubit acts as flag states for certain errors. As such, manipulating the state of the system to counteract an error may not be necessary; rather, when errors occur the result of a gate may be filtered out, or performed again. In other cases, the error state may simply be recorded as an indication of quality of the state of the system. The techniques for performing two-qubit gates described herein may also be compatible with different bosonic encodings of logical qubits, of which illustrative examples are described below. As used herein, a “two-qubit gate” refers to an entangling gate that acts between two logical qubits.

According to some embodiments, the techniques described herein may be applied within a system in which two bosonic modes are coupled via a programmable beamsplitter interaction (e.g., implemented by a coupling element between two bosonic systems), and in which an ancilla qubit is dispersively coupled to one of the bosonic modes. The techniques may provide for two-qubit gates to be applied on the bosonic modes while providing for a natural means of detecting errors via the state of the ancilla qubit. For instance, the state of the ancilla qubit may act as a ‘flag’ for errors, such that measurement of the ancilla qubit state subsequent to the two-qubit gate may indicate whether or not an error occurred during the two-qubit gate, with one or more states of the ancilla qubit being associated with an error, and one or more states of the ancilla qubit being associated with no error.

According to some embodiments, the system in which two bosonic modes are coupled via a programmable beamsplitter interaction may be implemented as a cQED system comprising two quantum oscillators (e.g., microwave cavity resonators) coupled together via a suitable coupling element such as a transmon qubit, a superconducting nonlinear asymmetric inductive element (SNAIL) or a superconducting quantum interference device (SQUID). One of the quantum oscillators may be coupled to an ancilla qubit (e.g., a transmon qubit). Although the ancilla qubit only couples to one of the bosonic modes of the system, due to the beamsplitter interaction provided by the coupling element, both bosonic modes interact with the ancilla qubit, enabling various two-mode operations. Two-qubit gates may be performed upon the bosonic modes through application of energy (e.g., microwave pulses) applied to the ancilla qubit and/or to the coupling element, as described further below.

According to some embodiments, the system in which two bosonic modes are coupled via a programmable beamsplitter interaction may be implemented as a cQED system comprising two dual-rail qubits, each implemented as a pair of quantum oscillators (e.g., microwave cavity resonators). In a dual-rail encoding, a photon is stored in one of the two oscillators; the photon in the first oscillator is treated as a logical 0, and the photon in the other oscillator is treated as a logical 1. Thus together the two oscillators form a single logical dual-rail qubit. The dual-rail encoding arrangement has several benefits: (i) photon loss appears as an erasure error; (ii) the single photon state is the lowest energy state of the oscillator and thereby has the lowest error rate of any state of the oscillator and as such the dual-rail encoding minimizes the rate of loss errors; and (iii) photon gains or losses are readily detectable by measuring the joint parity of the oscillators. Each dual-rail qubit acts as one of the bosonic modes, and the two dual-rail qubits may be coupled together via a suitable coupling element—in particular, one of the oscillators in one dual-rail qubit is coupled to one of the oscillators in the other dual-rail qubit. One of the oscillators that is coupled to an oscillator in the other dual-rail qubit may also be coupled to an ancilla qubit. Two-qubit gates may be performed upon the bosonic modes through application of energy (e.g., microwave pulses) applied to the ancilla qubit and/or to the coupling element that couples the two dual-rail qubits to one another, as described further below.

According to some embodiments, prior to performing a two-qubit gate the ancilla qubit may be driven into its ground state. Certain gates, described further below, may rely on the ancilla qubit being initially in its ground state prior to performing the gate, although at least one example is provided below in which this is not a requirement.

According to some embodiments, subsequent to performing a two-qubit gate, a state of the ancilla qubit is measured (e.g., through readout of a readout resonator dispersively coupled to the ancilla qubit). In some cases, when the state of the ancilla qubit is measured to be in the ground state subsequent to performing the two-qubit gate, this indicates that no error (or at least, no instance of certain types of errors) occurred during the two-qubit gate. Conversely, when the state of the ancilla qubit is measured to be in an excited state (including a first excited state or second excited state) subsequent to performing the two-qubit gate, this indicates that an error occurred during the two-qubit gate.

According to some embodiments, a two-qubit gate may be performed in part by applying energy to the coupling element that couples the two bosonic systems together, and this energy has an amplitude, frequency and duration selected based on the type of gate being performed. In some cases, the amplitude, frequency and duration (also referred to collectively herein as the “control parameters”) may be selected based on the bosonic encoding being utilized to store logical information in the bosonic systems, in addition to the type of gate being performed. In addition to such an operation, a two-qubit gate may also comprise one or more operations applied to the ancilla qubit, such as one or more rotations of the ancilla qubit's state, which may be performed through suitable control techniques. In general, a two-qubit gate may comprise applying energy to the ancilla qubit in one or more steps, and applying energy to the coupling element (with appropriate control parameters) in one or more steps distinct from those in which energy is applied to the ancilla qubit.

Following below are more detailed descriptions of various concepts related to, and embodiments of, techniques for performing error-detectable two-qubit gates. It should be appreciated that various aspects described herein may be implemented in any of numerous ways. Examples of specific implementations are provided herein for illustrative purposes only. In addition, the various aspects described in the embodiments below may be used alone or in any combination, and are not limited to the combinations explicitly described herein.

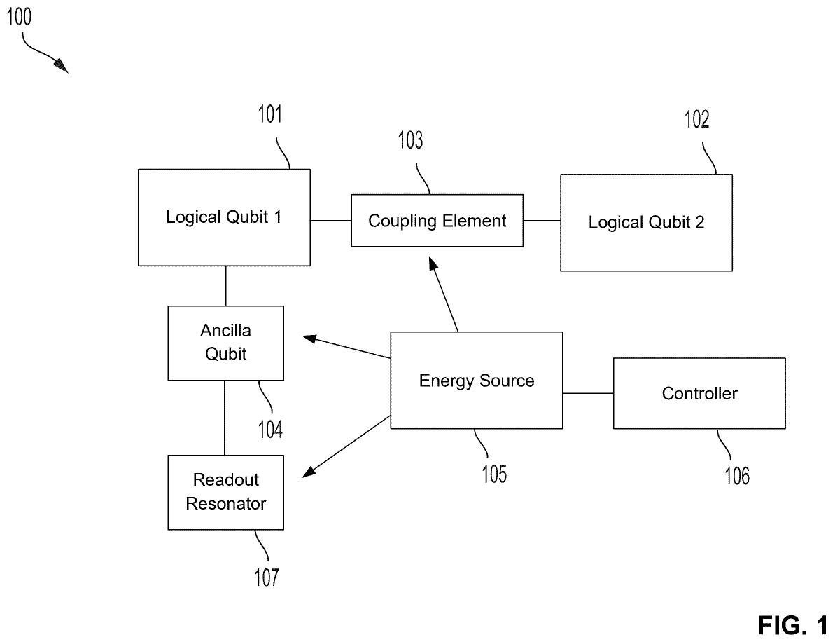

An illustrative system suitable for practicing the techniques described herein is shown in FIG. 1, according to some embodiments. In system 100, logical qubits 101 and 102 are coupled to one another via coupling element 103. The logical qubit 101 is also coupled to an ancilla qubit 104. Energy source 105 may be operated by controller 106 to direct energy to the ancilla qubit 104, the coupling element 103, and/or the readout resonator 107.

According to some embodiments, the logical qubit 101 and the logical qubit 102 each includes a cavity that supports quantum states of microwave photons. For example, in some embodiments, the first logical qubit 101 and the second logical qubit 102 may be a transmission line resonator or a three-dimensional cavity formed from a superconducting material, such as aluminum.

In some embodiments, the coupling element 103 may be a transmon qubit that is dispersively coupled to both the first logical qubit 101 and the second logical qubit 102. The coupling element 103 mediates coupling between the quantum states of the two logical qubits, allowing for interactions between the first logical qubit 101 and the second logical qubit 102. In some embodiments, the coupling element 103 may be a superconducting nonlinear asymmetric inductive element (SNAIL), a superconducting quantum interference device (SQUID) or some other non-linear element. In some embodiments, the ancilla qubit 104 may be a transmon qubit, a SNAIL, a SQUID or some other non-linear element.

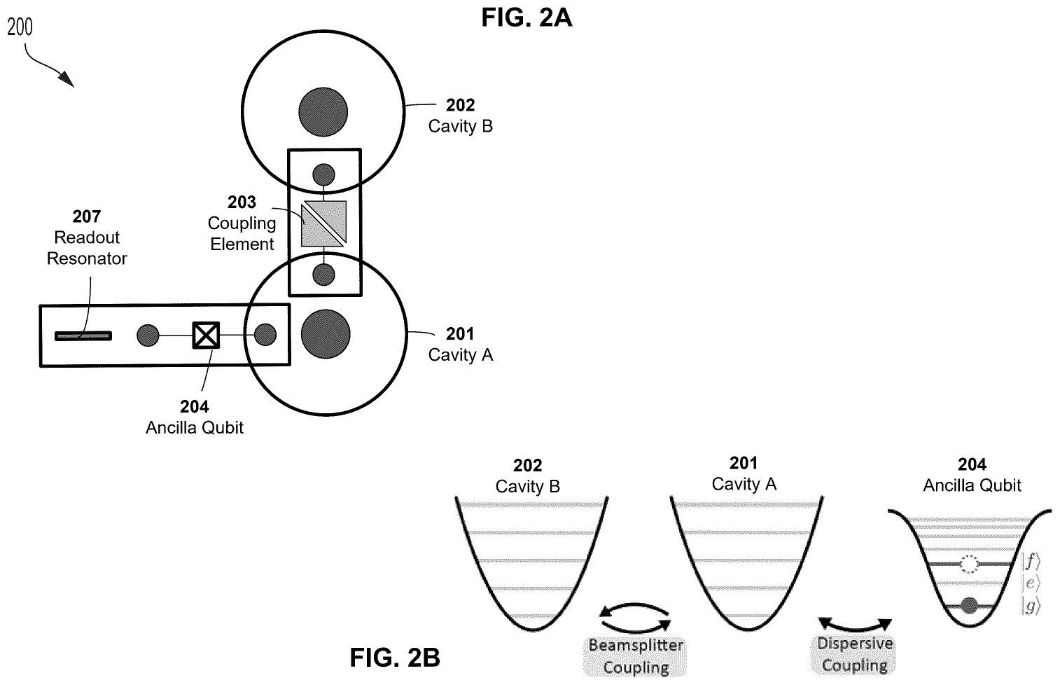

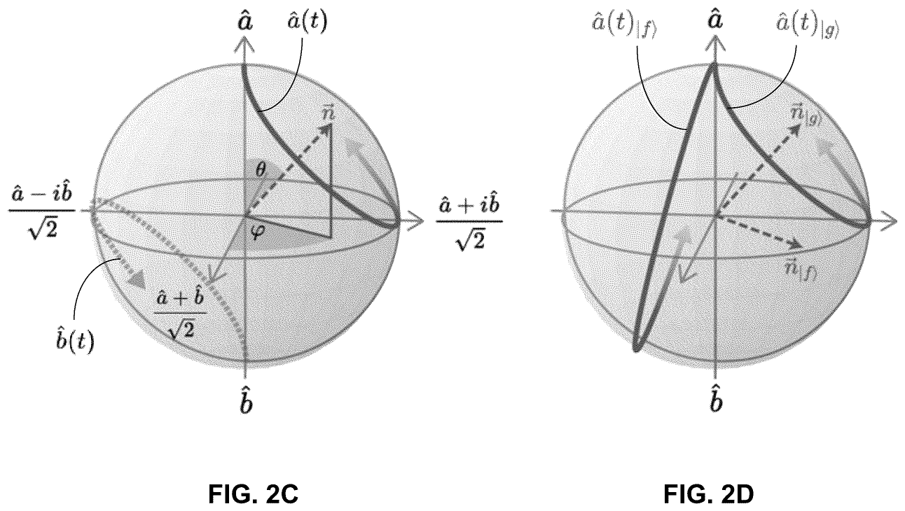

An illustrative implementation of system 100 is shown as system 200 in FIG. 2A. In this implementation, the logical qubits are implemented as bosonic modes stored in cavities 201 and 202 (e.g., microwave cavities). A microwave source (not shown in FIG. 2A) may be configured as the energy source 105 in this system and configured to direct microwave pulses of desired amplitudes, frequencies and phases to the ancilla qubit 204 (e.g., a transmon qubit), to the coupling element 203, and/or to the readout resonator 207. Such a microwave source may be coupled to the ancilla qubit and to the coupling element. The coupling between the microwave source and these components provides a way for the microwave source to apply microwave radiation to the components. In some embodiments, the energy source 105 may be capacitively coupled to each of the ancilla qubit 204, the coupling element 203, and the readout resonator 207.

In the example of FIG. 2A, the microwave source (not shown) may be operated to readout the state of the ancilla qubit 204. For instance, the readout resonator 207 may be arranged such that its resonant frequency (e.g., ˜GHz) is far from the transition frequency of the ancilla qubit 204 (e.g., dispersively coupled). The coupling between the ancilla qubit and readout resonator means that there is a shift in the resonator frequency that is dependent on the state of the qubit. This shift is small compared with the resonant frequency of the resonator (e.g., ˜MHz). As a result, sending a tone to the readout resonator 207 near the resonant frequency will be reflected by the resonator and the form of the reflected tone (also referred to herein as the “readout signal”) can be analyzed to determine the state of the ancilla qubit. In this manner, the state of the ancilla qubit 204 can be probed non-destructively by sending probe tones to the readout resonator 207, which is dispersively coupled to the qubit.

In the systems described herein, including the example of FIG. 2A, the entangling gates are based on a Hamiltonian that combines a beamsplitter interaction between the bosonic modes (e.g., implemented as the logical qubits 101 and 102 in FIG. 1, or as the cavities 201 and 202 in FIG. 2A), with a dispersive interaction between the ancilla qubit (e.g., ancilla qubit 104 in FIG. 1 or ancilla qubit 204 in FIG. 2A) and one of the bosonic modes (e.g., the bosonic mode of logical qubit 101 in FIG. 1 or the bosonic mode of the cavity 201 in FIG. 2A). This Hamiltonian may be written as:

$${χ BS}_{} = {χ}_{} + {BS}_{} ,$$

$$where$$

$${χ}_{} / ℏ = - \frac{χ}{2} {\hat{σ}}_{z} {\hat{a}}^{†} \hat{a} ,$$

$${BS}_{} / ℏ = \frac{{g}_{BS} ( t )}{2} ( {e}^{i φ ( t )} {\hat{a}}^{†} \hat{b} + {e}^{- i φ ( t )} \hat{a} {\hat{b}}^{†} ) + Δ ( t ) {\hat{a}}^{†} \hat{a} ,$$

and ô_{z}≡|g [symbol] [symbol] g|−|f [symbol] [symbol] f| is the Pauli Z operator in the two-level subspace defined by the |g [symbol] and |f [symbol] levels of the ancilla. A three-level ancilla is utilized in this example, which may have a benefit of allowing use of the |e [symbol] level for detecting a single ancilla decay event.

In the below, for purposes of illustration the interactions between the bosonic systems will be described with respect to the illustrative implementation of system 100 shown in FIG. 2A, although it will be appreciated that the techniques described herein are not limited to the particular implementation of FIG. 2A. As such, in the below description, references to logical qubits may refer to the logical information stored in each of the two cavities 201 and 202.

In the example of FIG. 2A, the term [symbol] _{BS}/ℏ represents the beamsplitter coupling between the cavities 201 and 202 as generated by the coupling element 203, and the term [symbol] _{λ}/ℏ represents the dispersive coupling between the cavity 201 and the ancilla qubit 204. These couplings are illustrated in FIG. 2B. In the Hamiltonian [symbol] _{λBS}, the annihilation operators â and \hat{b} act on the bosonic modes of cavities 201 and 202, respectively, g_{BS} (t) is the complex amplitude of the beamsplitter interaction between the cavities 201 and 202, Δ(t) is an effective detuning between two modes and λ is the strength of the dispersive interaction between the ancilla qubit 204 (in the gf-manifold) and mode â of the cavity 201. This Hamiltonian [symbol] _{λBS} is written in a frame where the dispersive interaction is symmetric, shifting the frequency of â by ±λ/2 dependent on the ancilla state.

Parameters of the Hamiltonian [symbol] _{λBS} may be controlled and varied through suitable selection of microwave drive signals applied to the coupling element 203 and to the ancilla qubit 204. For instance, the coupling strength g_{BS} (t), its phase φ(t), and detuning Δ(t) can all be rapidly varied via microwave drive techniques. As described below, operations including two-qubit gates can be engineered in this system by actuating microwave drives while engineering time-dependent control of these parameters, with different values of the parameters corresponding to different operations/gates. Although the ancilla qubit 204 couples to only one of the two bosonic modes of the cavities 201 and 202, in the presence of the beamsplitter interaction both modes interact with the ancilla qubit, thereby enabling various non-trivial two-mode operations.

To further explain the dynamics generated by [symbol] _{λBS}, an “operator Bloch sphere” is introduced, which utilizes conventional descriptions of single-qubit control on the Bloch sphere to explain the design of two-qubit gates for bosonic qubits.

Inspired by Schwinger's angular momentum formalism of bosonic operators, [symbol] _{BS} can be rewritten with the angular momentum operators

$${\hat{L}}_{I} = \frac{1}{2} ( {\hat{a}}^{†} \hat{a} + {\hat{b}}^{†} \hat{b} ) , {\hat{L}}_{X} = \frac{1}{2} ( {\hat{a}}^{†} \hat{b} + \hat{a} {\hat{b}}^{†} ) , \\ {\hat{L}}_{Y} = \frac{1}{2 i} ( {\hat{a}}^{†} \hat{b} - \hat{a} {\hat{b}}^{†} ) and {\hat{L}}_{Z} = \frac{1}{2} ( {\hat{a}}^{†} \hat{a} - {\hat{b}}^{†} \hat{b} ) ,$$

which allows [symbol] _{BS} to be rewritten as:

$${BS}_{} ( g , φ , Δ ) / ℏ = {g}_{BS} cos φ {\hat{L}}_{X} - {g}_{BS} sin φ {\hat{L}}_{Y} + Δ {\hat{L}}_{Z} + Δ {\hat{L}}_{I} .$$

For the case where the parameters g_{BS}, φ, Δ are constant, the Heisenberg representation of the mode operators can be obtained by transforming the mode operators via the unitary operator Û=exp (−i [symbol] _{BS}t/h),

$$( \begin{matrix}\hat{a} ( t ) \\ \hat{b} ( t )\end{matrix} ) = ( \begin{matrix}\hat{U} \hat{a} {\hat{U}}^{†} \\ \hat{U} \hat{b} {\hat{U}}^{†}\end{matrix} ) = {e}^{- i \frac{Δ}{2} t} {R}_{\vec{n}} ( Ω t ) ( \begin{matrix}\hat{a} \\ \hat{b}\end{matrix} ) ,$$

where

$${R}_{\vec{n}} ( Ω t ) = ( cos \frac{Ω t}{2} I - i sin \frac{Ω t}{2} \vec{n} \cdot \vec{σ} )$$

is a matrix in SU (2), which can be interpreted as a rotation around a precession vector \vec{n}= [sinθcosφ,−sinθ sinφ, cosθ] at rate Ω=\sqrt{g_{BS}²+Δ²}. The polar angle of the precession vector is determined by the ratio of the coupling strength g_{BS} and the detuning Δ such that cosθ=Δ/\sqrt{g_{BS}²+Δ²} and sinθ=g_{BS}/\sqrt{g_{BS}²+Δ²}.

Analogous to state evolution on a qubit Bloch sphere, the mode transformations may be plotted at each point in time to form trajectories on the operator Bloch sphere as shown in FIG. 2C. In the example of FIG. 2C, the north pole represents the initial mode operator â and the solid arrow represents the trajectory of the transformed mode operator â (t). Similarly, the south pole represents the initial mode operator b and the dashed arrow represents the trajectory of the transformed mode operator b (t). The trajectory can be fully controlled by modulating the complex amplitude of the beamsplitter interaction, which can be performed in a cQED system such as system 200 by sending a microwave pulse to the coupling element 203 and by setting the amplitude, duration and phase of the complex amplitude g_{BS} of the pulse to desired values. The trajectories from the north and south pole are antipodal to one another and therefore only show the transformation of â is shown henceforth. The end points of the trajectories shown in FIG. 2C indicate the final mode transformations of the original â, \hat{b} operators.

The effect of the ancilla's interaction, [symbol] _{λ}, appears as an ancilla-state-dependent detuning

$$Δ = {Δ}^{′} \pm \frac{χ}{2}$$

where Δ′ now represents the detuning of the beamsplitter drives from resonance. The dispersive beamsplitter Hamiltonian can now be rewritten as

$${χ BS}_{} = {B S}_{} ( {g}_{BS} , φ , {Δ}^{′} - \frac{χ}{2} ) ⊗ \vert g 〉 〈 g \vert + {B S}_{} ( {g}_{BS} , φ , {Δ}^{′} + \frac{χ}{2} ) ⊗ \vert f 〉 〈 f \vert .$$

Since the total detuning of the beamsplitter becomes dependent on the ancilla state, there now exist two different “conditional” precession vectors with different z-components, allowing one to construct ancilla-controlled mode trajectories, which are unitaries in which the identity is performed on the bosonic modes if the ancilla qubit is in its ground state |g [symbol] , and in which a unitary gate is performed on the bosonic modes if the ancilla is in its second excited state |f [symbol] . Illustrative ancilla-controlled mode trajectories are illustrated in FIG. 2D, and are denoted â (t)_{|g} [symbol] and â( [symbol] , respectively.

All possible dynamics generated by the detuned beamsplitter Hamiltonian [symbol] _{BS} can be represented on the operator Bloch sphere. The three degrees of freedom in the dispersive beamsplitter Hamiltonian g_{BS} (t), φ(t), and Δ(t) determine the axis and rate of precession. This holds true even when these parameters have time dependence, which leads to time-varying precession axes and precession rates. The operator Bloch sphere picture is necessary to visualize the time dynamics generated by a continuous beamsplitter interaction, over which we have fine control of the Hamiltonian parameters. This differs, for instance, from the discrete beamsplitter transformations found in linear optics.

The operator Bloch sphere picture is a powerful tool for finding new and interesting ancilla-controlled unitaries generated by [symbol] _{λBS}. Below, an approach to realize both cZZ_{L} and cSWAP_{L} is described with respect to the illustrative hardware implementation shown in FIG. 2A (the subscripts L serve as a reminder that these gates are performed on a logical qubit).

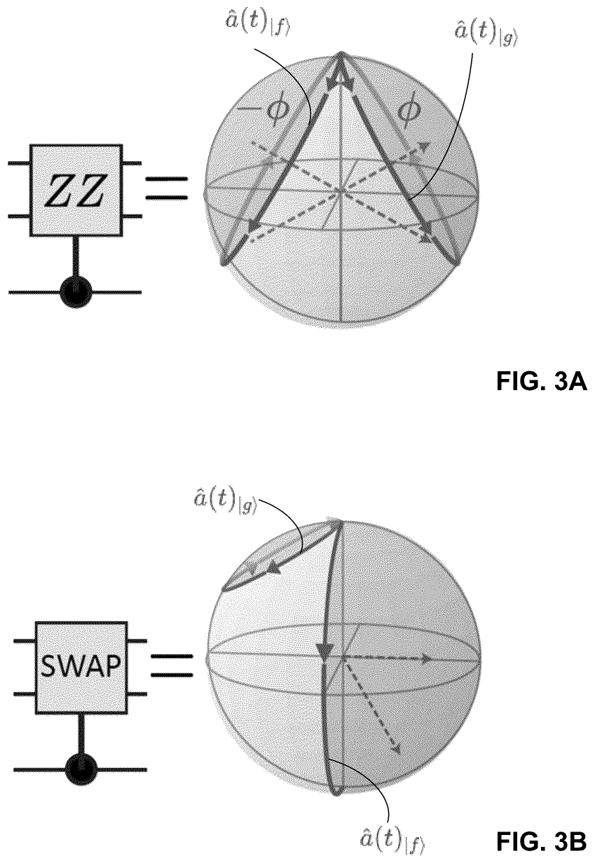

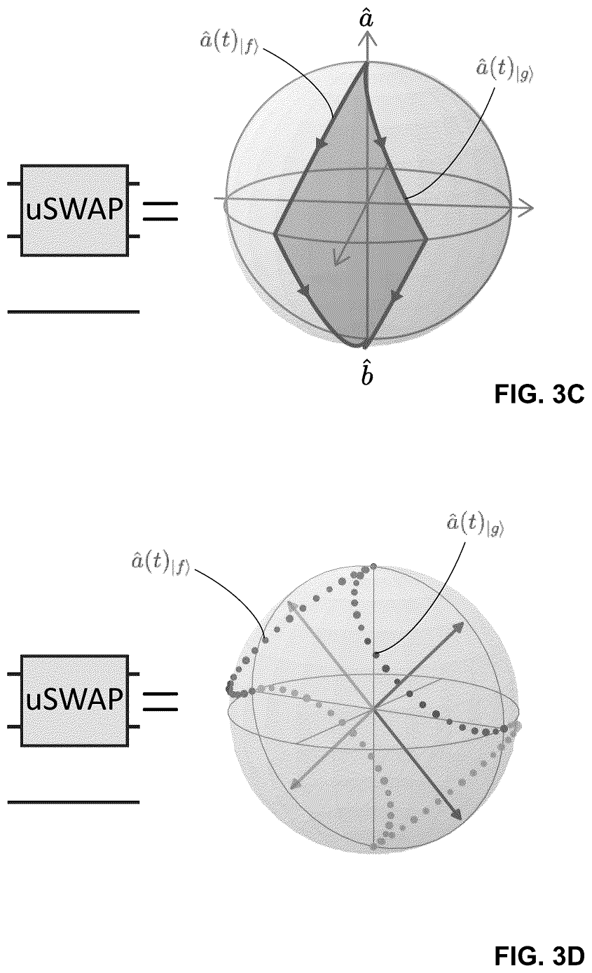

At the end of an ancilla-controlled unitary, the bosonic states return to the logical codespace, which restricts the analysis to trajectories that start and end at the poles of the operator Bloch sphere, corresponding to either SWAP or identity operations. However, an important feature is that the solid angle enclosed by these trajectories determines the geometric phase imparted to the bosonic modes, and can be used as a resource to enact logical operations. This effect is the basis of engineered ancilla-controlled ZZ_{L}, cZZ_{L}, and ancilla-controlled SWAP, cSWAP gates, which are shown in FIGS. 3A-3B. Moreover, by combining these unitaries with arbitrary ancilla rotations, a family of excitation-preserving gates can be constructed, such as the ZZ_{L} (θ), iSWAP(θ) and fSim (θ₁, θ₂) gates, to be performed on the logical subspace.

Designing trajectories that enclose a specific geometric phase can be used to build useful unitaries. The geometric phase is set by the term

$${e}^{- i \frac{Δ}{t} t}$$

in the above equation for

$$( \begin{matrix}\hat{a} ( t ) \\ \hat{b} ( t )\end{matrix} ) .$$

Completely enclosing a solid angle ϕ corresponds to performing the unitary

$${\hat{R}}_{ϕ} = {e}^{i \frac{ϕ}{2} ( {\hat{a}}^{†} \hat{a} + \hat{{b}^{†}} \hat{b} )}$$

on the bosonic modes. For many bosonic encodings,

$${e}^{i \frac{π}{n} {\hat{a}}^{†} \hat{a}} = {Z}_{L}$$

for n ∈ [symbol] and hence

$$Z {Z}_{L} = {e}^{i \frac{π}{n} ( {\hat{a}}^{†} \hat{a} + \hat{{b}^{†}} \hat{b} )} .$$

This is true, for instance, for binomial codes and 4-legged cat codes. Therefore, by varying the relative strengths of the microwave-controlled Hamiltonian parameters, the enclosed geometric phase can be chosen to match the ZZ_{L} operator for a particular bosonic code. Moreover, the ability to map the system dynamics to trajectories on a Bloch sphere also allows us to import noise mitigation and gate optimization techniques developed for qubits that utilize geometric phase control.

Trajectories that depend on the states of the ancilla qubit |g [symbol] and |f [symbol] generate three types of ancilla-controlled unitaries that return to the codespace:
(1) Both trajectories return to the starting pole;
(2) One trajectory returns to the starting pole whilst the other returns to the opposite pole; or
(3) Both trajectories return to the opposite pole.
   Although these trajectories are a small subset of all the possible trajectories that can be engineered, each case represents a different, useful ancilla-controlled logical operation.

To consider this further, consider the evolution of trajectory type (1) in which the two trajectories conditioned on the ancilla qubit's state return to their starting poles (see FIG. 3A). The geometric phase accumulation ¢ means the following ancilla-controlled unitary is performed:

$${e}^{+ i \frac{ϕ}{2} ( {\hat{a}}^{†} \hat{a} + \hat{{b}^{†}} \hat{b} )} ⊗ \vert g 〉 〈 g \vert + {e}^{- i \frac{ϕ}{2} ( {\hat{a}}^{†} \hat{a} + \hat{{b}^{†}} \hat{b} )} ⊗ \vert f 〉 〈 f \vert .$$

The geometric phase accumulation can be used to perform logical operations on the bosonic modes of the cavities 201 and 202. For many bosonic encodings, Z_{L} takes the form

$${e}^{i \frac{π}{n} {a}^{†} a}$$

for a code with n-fold rotational symmetry and hence

$$Z {Z}_{L} = {e}^{i \frac{π}{n} ( {\hat{a}}^{†} \hat{a} + \hat{{b}^{†}} \hat{b} )} .$$

### When

$$ϕ = \frac{π}{n} or ϕ = 2 π ( 1 - \frac{1}{2 n} )$$

this is equivalent to the cZZ_{L} unitary

$$⊗ \vert g 〉 〈 g \vert + Z {Z}_{L} ⊗ \vert f 〉 〈 f \vert ,$$

up to the rotation operator

$${e}^{- i \frac{π}{2 n} ( {\hat{a}}^{†} \hat{a} + \hat{{b}^{†}} \hat{b} )} ,$$

which can be tracked by a controller operating the system.

The required Hamiltonian parameters are found from the general formula for the solid angle, ϕ. For orbits about a fixed precession vector, this is given by

$$ϕ = 2 π ( 1 - cos ( θ ) ) = 2 π ( 1 - \frac{χ}{2 Ω} ) .$$

The parameters for a cZZ_{L} gate are shown in Table 1 below for bosonic codes where

$${Z}_{L} = {e}^{i π {\hat{a}}^{†} \hat{a}} or {Z}_{L} = {e}^{i \frac{π}{2} {\hat{a}}^{†} \hat{a}} .$$

Since the interaction strengths g_{BS}/2π and λ/2π may both be several MHz, all of these gates on multiphoton encoded qubits may be performed in times ˜ 1 μs, 3 orders of magnitude faster than typical microwave cavity decay rates (1 ms), and 2 orders of magnitude faster than transmon decoherence rate (100 μs), which yields the coherence-limited infidelity at the level of p_{phys} ∂τ_{gate}/T_{coh}˜ 1-10% similar scaling as previously implemented bosonic entangling gate.

TABLE 1
Pump Conditions for Operations

| Parameter of | cZZ_{L} for Fock 01 | cZZ_{L} for binomial | |
|---|---|---|---|
| Hamiltonian [symbol] _{χBS} | or dual-rail | or 4-cat | cSWAP |
| g_{BS} | $\frac{\sqrt{3}}{2} χ$ | $\frac{\sqrt{15}}{2} χ$ | $\frac{χ}{\sqrt{3}}$ |
| Δ | 0 | 0 | $\frac{χ}{2}$ |
| T | $\frac{2 π}{χ}$ | $\frac{π}{χ}$ | $\frac{\sqrt{3} π}{χ}$ |

The binomial codes and 4-cat codes described above represent alternative logical encodings to the Fock 01 encoding or dual-rail encodings described herein, and are defined as follows. The logical codewords are defined for the lowest order binomial code are

$$\vert {0}_{L} 〉 = \frac{\vert 0 〉 + \vert 4 〉}{\sqrt{2}}$$

$$\vert {1}_{L} 〉 = \vert 2 〉$$

The (even photon number) 4-legged cat code is based on superpositions of coherent states and is defined as:

$$\vert {0}_{L} 〉 = \frac{\vert α 〉 + \vert i α 〉 + \vert - α 〉 + \vert - i α 〉}{\sqrt{{N}_{0}}}$$

$$\vert {1}_{L} 〉 = \frac{\vert α 〉 - \vert i α 〉 + \vert - α 〉 - \vert - i α 〉}{\sqrt{{N}_{1}}}$$

Where N₀ and N₁ are normalization factors. Both encodings share a similar photon number structure, with the |0 [symbol] _{L}, and |1 [symbol] _{L} states containing the same average number of photons in the large a limit. Codewords contain only even number of photons, allowing photon loss to be detected via photon number parity measurements after applying a two-qubit gate.

Returning to the required Hamiltonian parameters to formulate a desired gate, with a different set of Hamiltonian parameters, the cSWAP (controlled SWAP) gate shown in FIG. 3B can be defined as:

$$⊗ \vert g 〉 〈 g \vert + SWAP ⊗ \vert f 〉 〈 f \vert$$

In this case, the trajectory is conditioned on |f [symbol] to end at the opposite pole whilst the trajectory conditioned on |g [symbol] completes an orbit about a different precession vector to return to the initial pole (trajectory type (2) above). For the parameters presented in Table 1 for the cSWAP gate, this implements the unitary

$${e}^{i π ( 1 - \frac{\sqrt{3}}{2} ) ( {\hat{a}}^{†} {\hat{a}}^{†} + {\hat{b}}^{†} {\hat{b}}^{†} )} ⊗ \vert g 〉 〈 g \vert + {e}^{- i \frac{π}{2} ( {\hat{a}}^{†} {\hat{a}}^{†} + {\hat{b}}^{†} {\hat{b}}^{†} )} SWAP ⊗ \vert f 〉 〈 f \vert$$

By performing a sequence of operations that include this unitary in addition to one or more delays, unwanted geometric phase accumulations can be mitigated to realize the cSWAP unitary.

Finally, when both trajectories end at the opposite pole (trajectory type (3) above), a SWAP may be performed between the bosonic modes of the cavities 201 and 202 that is independent of the ancilla state (up to geometric phase accumulation), which is referred to herein as an “unconditional SWAP” gate. With a conventional framework this operation is hard to realize when the ancilla is in a superposition of states, due to the static nature of the dispersive interaction. The unconditional SWAP is a useful operation that allows for an extension of ancilla-controlled unitaries that act on more than two bosonic modes.

An example of the unconditional SWAP (or uSWAP) gate with the trajectory described is shown in FIG. 3C. These trajectories can be can be engineered by detuning the parametric beamsplitter by λ_{gf}/2 and g_{BS}≥λ_{gf}/2. Once the trajectories reach the equator of the Operator Bloch Sphere, a n-pulse may be performed in the g−f manifold to effectively reverse the detunings. This does not implement a true unconditional SWAP unitary but rather the unitary

$${\hat{R}}_{{ϕ}_{g}} \vert g 〉 〈 g \vert + {\hat{R}}_{{ϕ}_{f}} SWAP ⊗ \vert f 〉 〈 f \vert$$

$$= {\hat{R}}_{{ϕ}_{g}} ( SWAP \vert g 〉 〈 g \vert + {\hat{R}}_{{ϕ}_{f} - {ϕ}_{g}} SWAP ⊗ \vert f 〉 〈 f \vert )$$

With this approach, unwanted conditional rotations are reversed by performing delays before and after the unitary above and using the dispersive interaction, or by finding trajectories such that \hat{R}_{ϕ}_{_{f}}_{-ϕg}= [symbol] .

One alternative to the above approach for performing a uSWAP gate is to instead detune the beamsplitter coupling by λ/2 and set g_{BS}=|λ|/2 such that the polar angle of both precession vectors is 45°. After applying this Hamiltonian for time t=\sqrt{2}π/λ, both trajectories reach the equator and are antipodal. If the sign of the beamsplitter drive is then flipped such that g_{BS}=−|λ|/2, then after the same duration both trajectories will reach the south pole at the same time. The area between these trajectories on the Operator Bloch Sphere is 21 steradians. This trajectory is shown in FIG. 3D.

The above ‘building block’ operations of cZZ_{L} and cSWAP can be combined with arbitrary rotations on the ancilla qubit to perform a continuous family of entangling gates on the bosonic logical subspace. The cSWAP and cZZ_{L} operations by themselves only generate entanglement between the ancilla qubit 204 and the bosonic modes of the cavities 201 and 202. However, with this circuit an entangling gate may be performed that acts only on the bosonic modes, leaving the ancilla disentangled at the end of the circuit. The ancilla should therefore start and end in its initial state, |g [symbol] . As described above, an advantage of this approach is that by checking whether the ancilla returns to |g [symbol] ancilla errors that occurred during the gate may be detected. That is, if the ancilla returns to |g), no such errors have occurred, otherwise if the ancilla is in |e [symbol] or |f [symbol] , an error is detected.

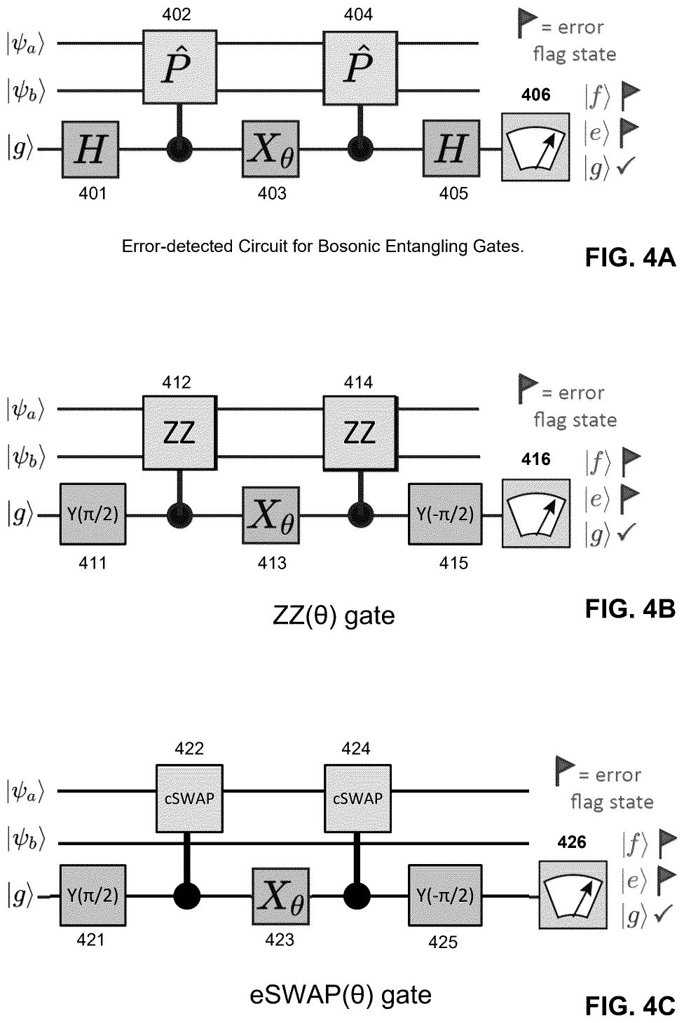

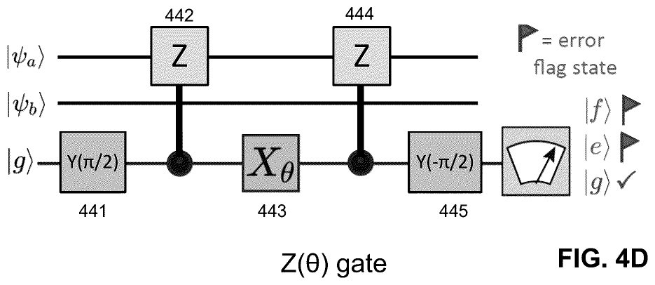

FIG. 4A depicts the general case of an error-detection circuit for bosonic entangling gates, according to some embodiments. In FIG. 4A (and in FIGS. 4B and 4C), the first line |ψₐ [symbol] represents operations performed on the cavity 201, the second line |ψ_{b} [symbol] represents operations performed on the cavity 202, and the third line |g [symbol] represents operations performed on the ancilla qubit, which is initially in its ground state |g [symbol] . The gate shown in FIG. 4A may be performed by operating the systems of FIG. 1 or 2A as described above (e.g., by operating the energy source 105 in the system of FIG. 1, or by operating a microwave source to supply microwave energy to elements of the system of FIG. 2A).

In the example of FIG. 4A, the operation \hat{P} (operations 402 and 404) performed on the bosonic modes of the cavities 201 and 202 is the following exponentiation circuit:

$$\hat{P} ( θ ) = exp ( - i \frac{θ}{2} \hat{P} ) = cos \frac{θ}{2} \hat{I} - i sin \frac{θ}{2} \hat{P}$$

This operation is derived from the ancilla controlled unitary c\hat{P}, where \hat{P} is any “Pauli-like” operator acting on the two-qubit logical subspace that satisfies \hat{P}²= [symbol] (in other words \hat{P} is Hermitian and unitary). The full unitary implemented on the qubit-ancilla system by the circuit of FIG. 4A is

$$\hat{P} ( θ ) ⊗ \vert g 〉 〈 g \vert + \hat{P} ( - θ ) ⊗ \vert f 〉 〈 f \vert .$$

The exponentiation circuit provides an elegant way to control multiple logical qubits and also has desirable error detection properties. By varying the angle of the middle ancilla rotation Xe (operation 403), any of a number of parameterized entangling gates \hat{P}(θ) may be implemented on the logical qubits. The rest of the gate construction remains unchanged, allowing logical gates to be calibrated for many different values of θ. In the example of FIG. 4A, operations 401 and 405 are Hadamard gates H, which each creates an equal superposition of the two basis states (e.g., maps |0 [symbol] to |+ [symbol] and |1 [symbol] to |− [symbol] ).

The circuit depicted in the example of FIG. 4A allows for detection of a single ancilla dephasing error in addition to ancilla decay events by measuring the state of the ancilla qubit in operation 406. The state of the ancilla qubit acts as a flag to indicated whether or not the gate represented by operations 401, 402, 403, 404 and 405 was performed without ancilla dephasing or ancilla decay errors. In particular, if the state of the ancilla qubit is the ground state |g [symbol] after performing operations 401, 402, 403, 404 and 405, this indicates no such error occurred. Otherwise, if the state of the ancilla qubit is the first excited state |e [symbol] or the second excited state |f [symbol] , this indicates that at least one such error occurred while performing operations 401, 402, 403, 404 and 405. This error detection approach provides of use of an ancilla qubit that may be considerably more noisy than the logical qubits, since the propagation of ancilla errors to the logical qubits is error-detectable to first order.

When an error is detected, the system may be operated in various ways. For example, in cases in which a circuit is comparatively short with many gates performed, results that were produced when an error occurred may be filtered out. In use cases where the gates are performed at least in part to prepare resource states (e.g., entangled states) for use in a larger computation, or in short-depth circuits used in quantum algorithms, the presence or absence of an error can be used to indicate the quality of the resource state.

As one illustrative implementation of the circuit of FIG. 4A, setting \hat{P}=ZZ with the cZZ_{L} unitary yields a construction for the ZZ_{L}(θ) gate, as shown in FIG. 4B. Here, the initial rotation operation 411 is performed as

$$Y ( \frac{π}{2} ) ,$$

also referred to as Y₊, rather than a Hadamard gate, as it also results in the |0 [symbol] state being mapped to |+ [symbol] , but is easier in practice to implement. Similarly, the final operation 415 is performed as also

$$Y ( \frac{- π}{2} ) ,$$

also referred to as Y₋. The cZZ_{L} unitary applied in each of operations 412 and 414:

$$⊗ \vert g 〉 〈 g \vert + {ZZ}_{L} ⊗ \vert f 〉 〈 f \vert ,$$

may be applied as described above by operating the energy source with the appropriate values of g_{BS}, Δ and T as shown in Table 1.

As with the example of FIG. 4A, the circuit depicted in the example of FIG. 4B allows for detection of a single ancilla dephasing error in addition to ancilla decay events during the ZZ gate by measuring the state of the ancilla qubit in operation 416. The state of the ancilla qubit acts as a flag to indicated whether or not the gate represented by operations 411, 412, 413, 414 and 415 was performed without ancilla dephasing or ancilla decay errors. In particular, if the state of the ancilla qubit is the ground state |g [symbol] after performing operations 411, 412, 413, 414 and 415, this indicates no such error occurred. Otherwise, if the state of the ancilla qubit is the first excited state |e [symbol] or the second excited state |f [symbol] , this indicates that at least one such error occurred while performing operations 411, 412, 413, 414 and 415.

As another illustrative implementation of the circuit of FIG. 4A, setting \hat{P}=SWAP with the cSWAP unitary yields a construction for the exponential-SWAP (eSWAP) gate, as shown in FIG. 4C). The cSWAP unitary applied in each of operation 422 and operation 424:

$${e}^{i π ( 1 - \frac{\sqrt{3}}{2} ) ( {\hat{a}}^{†} {\hat{a}}^{†} + {\hat{b}}^{†} {\hat{b}}^{†} )} ⊗ \vert g 〉 〈 g \vert + {e}^{- i \frac{π}{2} ( {\hat{a}}^{†} {\hat{a}}^{†} + {\hat{b}}^{†} {\hat{b}}^{†} )} SWAP ⊗ \vert f 〉 〈 f \vert$$

may be applied as described above by operating the energy source with the appropriate values of g_{BS}, Δ and T as shown in Table 1.

As with the example of FIG. 4A, the circuit depicted in the example of FIG. 4C allows for detection of a single ancilla dephasing error in addition to ancilla decay events during the eSWAP gate by measuring the state of the ancilla qubit in operation 426. The state of the ancilla qubit acts as a flag to indicated whether or not the gate represented by operations 421, 422, 423, 424 and 425 was performed without ancilla dephasing or ancilla decay errors. In particular, if the state of the ancilla qubit is the ground state |g [symbol] after performing operations 421, 422, 423, 424 and 425, this indicates no such error occurred. Otherwise, if the state of the ancilla qubit is the first excited state |e [symbol] or the second excited state |f [symbol] , this indicates that at least one such error occurred while performing operations 421, 422, 423, 424 and 425.

In each of the examples of FIGS. 4A-4C, the angle θ of the Xe operations 403, 413 or 423 may be varied, which is controlled by varying the angle of the intermediate ancilla rotation. The choice of the value of θ produces entanglement from separable input states for all values of θ except 0 and integer multiples of π. The gates are maximally entangling for θ=π/2, and

$${ZZ}_{L} ( \frac{π}{2} )$$

is equivalent to CNOT gate up to single qubit gates.

By combining eSWAP(θ) and ZZ_{L}(θ) with single qubit Z_{L}(θ) gates, any desired excitation-preserving logical two-qubit gate can be performed on the two bosonic qubits. A Z_{L}(θ) gate can be implemented by using the same construction as FIG. 4A, except with ancilla-controlled rotations of a single bosonic mode, as for example shown in FIG. 4D with ancilla qubit rotations 441, 443 and 445, and single bosonic mode rotations 442 and 444. Alternatively, a Z_{L}(θ) gate may be implemented using a fault-tolerant Selective Number-dependent Arbitrary Phase (SNAP) gate, such as those gates described in U.S. Pat. No. 10,540,602, titled “Techniques of Oscillator Control for Quantum Information Processing and Related Systems and Methods,” which is hereby incorporated by reference in its entirety.

The above construction can also be used when the bosonic states of the logical qubits are encoded using GKP codewords. With conditional displacement Hamiltonians, the ancilla-controlled unitaries cZ_{L}, cZZ_{L}, cX_{L}, cXX_{L} etc. can be engineered, which in turn allows for implementation of the gates Z_{L}(θ),ZZ_{L}(θ),X_{L} (θ),XX_{L} (θ). In other words, the construction allows for the realization of parameterized entangling gates and arbitrary single-qubit rotations in the GKP code, whilst being able to detect ancilla errors during the gate. cQED allows for the direct implementation of the required ancilla-controlled unitaries by stringing together conditional displacements that act on different bosonic modes coupled to the same ancilla to construct joint conditional displacements.

Another powerful application of the ancilla-controlled logical gates is to perform a OND logical measurement of the operator \hat{P}. This is carried out by preparing the ancilla in |+ [symbol] _{gf}=(|g [symbol] +|f [symbol] )/\sqrt{2}, applying c\hat{P} and then measuring the ancilla in the |± [symbol] _{gf} basis. For cSWAP this amounts to a SWAP test. Similarly, cZZ_{L} can be turned into a QND logical measurement of the ZZ_{L} operator. This operation finds use in measurement-based alternatives to entangling gates and can form part of a Bell measurement. Unlike the gate construction, in principle these measurements can correct single ancilla decay errors and all orders of ancilla dephasing.

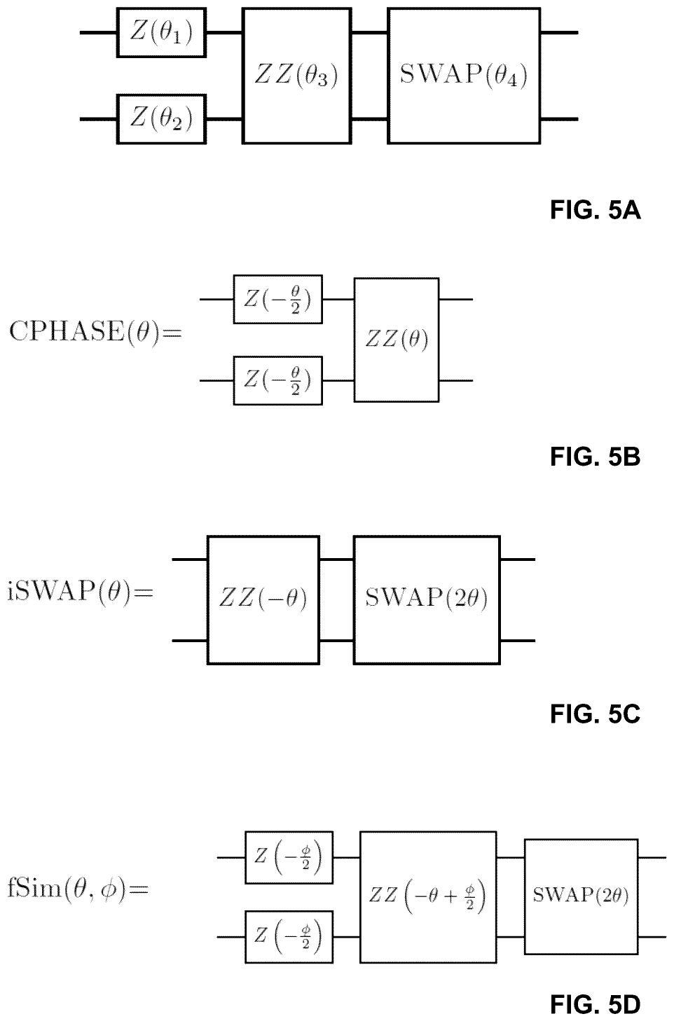

Using the parametrized eSWAP(θ) and ZZ_{L}(θ) gates described above, any desired two-qubit gate that conserves the total number of excitations in the encoded subspace may be constructed. A general excitation-preserving two-qubit gate can be parameterized by the circuit shown in FIG. 5A, which includes a single qubit Z_{L}(θ) gate performed on the bosonic mode of each logical qubit (as described above in relation to FIG. 4D), a ZZ_{L}(θ) gate (as described above in relation to FIG. 4B), and an eSWAP(θ) gate (as described above in relation to FIG. 4C).

With particular choices of θ₁, θ₂, θ₃ and θ₄, useful gate families can be generated. For instance, the CPHASE (θ), iSWAP(θ), and fSim (θ, ϕ) gates shown in FIGS. 5B, 5C and 5D, respectively, may be formed from suitable choices for θ₁, θ₂, θ₃ and θ₄.

One approach to implement the above-described techniques for performing error detecting two-qubit gates is within the system of FIG. 2A, as described above. However, these techniques may be applied in any other suitable system in which two logical qubits are coupled to one other with a beamsplitter coupling as described by [symbol] _{BS} and in which one of the logical qubits is coupled to an ancilla qubit. Another example of such a system is one in which each logical qubit is implemented as a dual rail qubit.

As described above, in a dual-rail qubit a photon is stored in one of two oscillators; the photon in the first oscillator is treated as a logical 0, and the photon in the other oscillator is treated as a logical 1. Thus together the two oscillators form a single logical dual-rail qubit. Put another way, a dual rail qubit is a logical qubit that occupies two bosonic modes (â₁, \hat{b}₁) with codewords |0 [symbol] _{L}=|01 [symbol] and |1 [symbol] _{L}/=|10 [symbol] _{L}.

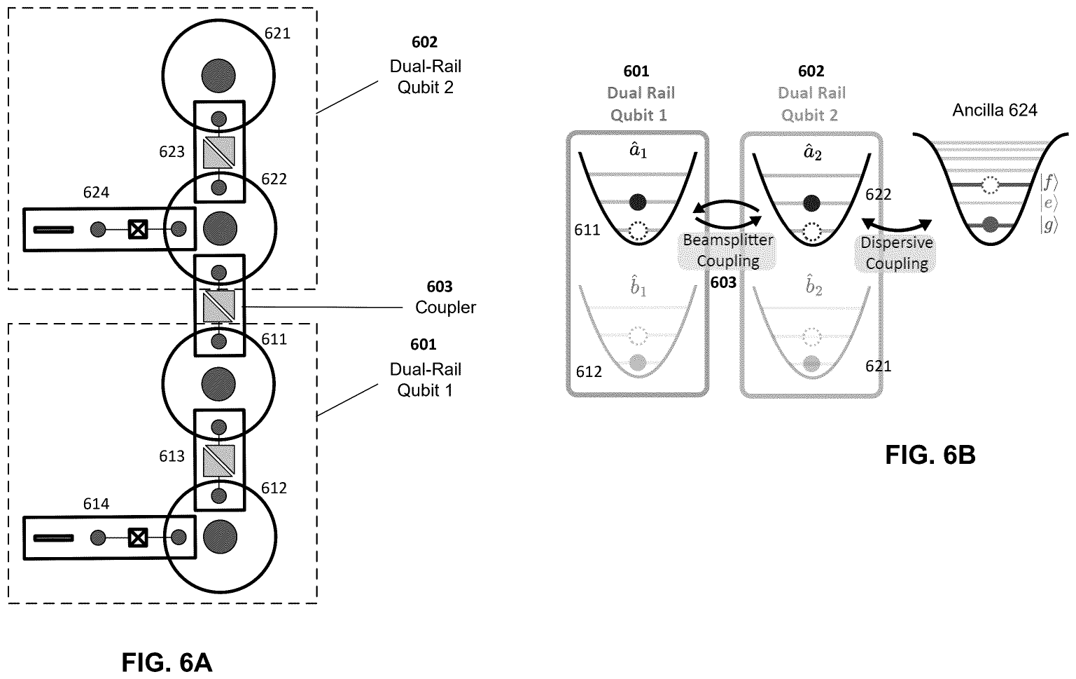

A system suitable for practicing the two-qubit gates described above with two dual-rail qubits as the logical qubits is depicted in FIG. 6A, according to some embodiments. In the example of FIG. 6A, a pair of dual-rail logical qubits 601 and 602 are depicted coupled to one another by a coupler 603. Dual-rail qubit 601 includes cavities 611 and 612 (e.g., microwave cavities), which are coupled together via coupling element 613; and dual-rail qubit 602 includes cavities 621 and 622 (e.g., microwave cavities), which are coupled together via coupling element 623. Each of cavities 612 and 622 is coupled to a respective ancilla qubit 614 or 624 (each may for instance be a transmon qubit) coupled to a respective readout resonator. Each of the coupling elements 603, 613, and 623 may be a superconducting nonlinear asymmetric inductive element (SNAIL), a superconducting quantum interference device (SQUID) or some other non-linear element.

Two-qubit gates as described above may be performed on the two dual-rail logical qubits by directing energy to the coupler 603 between the dual-rail qubits (instead of, for instance, the coupler 203 between the two logical qubits implemented by cavities 201 and 202 as in the example of FIG. 2A). When performing two qubit gates on a pair of dual-rail qubits, the ancilla qubit 624 that is coupled to cavity 622, which is coupled to cavity 611 of the other dual-rail qubit via coupler 603 may be operated as the ancilla qubit in the above two-qubit gate scheme. As such, operations such as operations 411, 413 and 415 may be applied to ancilla qubit 624, and any errors that occur during performance of the two qubit gate can be detected by measuring the state of the ancilla qubit 624 and determining whether the ancilla qubit is in the state |g [symbol] , |e [symbol] or |f [symbol] . The couplings depicted in FIG. 6A are further illustrated in FIG. 6B, indicating that modes (â₁, \hat{b}₁) comprise logical qubit 601 and (â₂, \hat{b}₂) comprise logical qubit 602.

Single qubit logical Z gates can be performed in the system of FIG. 6A by physically interacting with one of the bosonic modes in the dual-rail qubit. In particular, a Z gate can be performed via the unitary

$${Z}_{L} = {e}^{i π {\hat{a}}_{1}^{†} {\hat{a}}_{1}}$$

or equivalently via

$${Z}_{L} = {e}^{i π {\hat{b}}_{1}^{†} {\hat{b}}_{1}} .$$

This means that even though two dual-rail qubits comprise four physical modes, only two of them need to interact to perform logical two qubit gates and measurements. If (â₂, \hat{b}₂) are defined as the modes in a second dual-rail qubit, a logical ZZ_{L}(θ) gate can be performed by using an ancilla qubit coupled to mode â₂ and setting

$$\hat{P} = {e}^{i π ( {\hat{a}}_{1}^{†} {\hat{a}}_{1} + {\hat{a}}_{2}^{†} {\hat{a}}_{2} )} ,$$

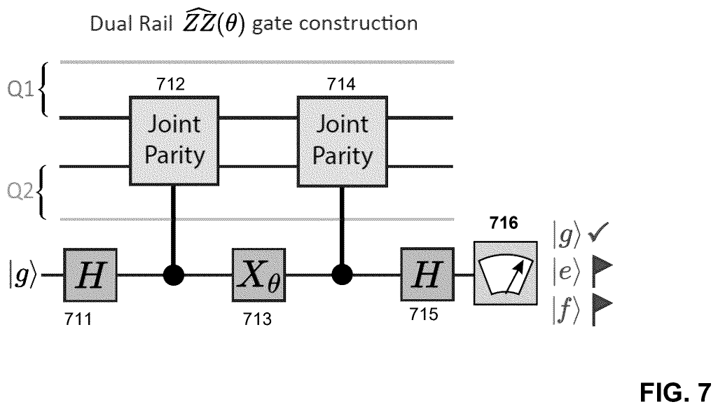

which is the joint parity operator. An illustrative ZZ_{L}(θ) gate for the dual-rail qubit is depicted in FIG. 7, according to some embodiments. In the example of FIG. 7, the ZZ_{L}(θ) gate includes the Hadamard gates 711 and 715 which each creates an equal superposition of the two dual-rail basis states (e.g., maps |0 [symbol] to |+ [symbol] and |1 [symbol] to |− [symbol] ), the joint parity operations

$${e}^{i π ( {\hat{a}}_{1}^{†} {\hat{a}}_{1} + {\hat{a}}_{2}^{†} {\hat{a}}_{2} )}$$

712 and 714, and an ancilla rotation operation X_{θ} 713.

As with the example of FIG. 4A, the circuit depicted in the example of FIG. 7 allows for detection of a single ancilla dephasing error in addition to ancilla decay events during the ZZ_{L}(θ) gate by measuring the state of the ancilla qubit in operation 716. The state of the ancilla qubit acts as a flag to indicated whether or not the gate represented by operations 711, 712, 713, 714 and 715 was performed without ancilla dephasing or ancilla decay errors. In particular, if the state of the ancilla qubit is the ground state |g [symbol] after performing operations 711, 712, 713, 714 and 715, this indicates no such error occurred. Otherwise, if the state of the ancilla qubit is the first excited state |e [symbol] or the second excited state |f [symbol] , this indicates that at least one such error occurred while performing operations 711, 712, 713, 714 and 715.

All logical gates in the dual-rail code conserve the total number of excitations in the system, and arbitrary single qubit rotations in dual-rail qubits can be realized with the beamsplitter interaction between the modes âᵢ and \hat{b}ᵢ. When combined with the ZZ_{L} (θ) gate this forms a universal gate set. In contrast, any bosonic code that uses only one bosonic mode per logical qubit by necessity requires gates that do not conserve the total number of excitations. e.g., an X gate in the Fock 01 code is \hat{X}_{Fock}=|0 [symbol] [symbol] 1|+|1 [symbol] [symbol] 0| which involves transitions between states with different photon number whereas \hat{X}_{Dual-rail}=|01 [symbol] [symbol] 10|+|10 [symbol] [symbol] 01| does not.

For the above-described gate and measurement constructions to be applied to the dual-rail code, it is desirable that the modes are bosonic with the ability to support up to two excitations in each mode. This is because constructions rely on Hong-Ou-Mandel-like interference when we start in the state |11 [symbol] ₐ_{₁}_{,a}_{₂}. The dual-rail code also has the ability to detect photon loss errors after the gate or measurement. One or both of the dual-rail qubits may end in the state |00 [symbol] ₐ_{ᵢ}_{,b}_{ᵢ}

Having thus described several aspects of at least one embodiment of this invention, it is to be appreciated that various alterations, modifications, and improvements will readily occur to those skilled in the art.

Such alterations, modifications, and improvements are intended to be part of this disclosure, and are intended to be within the spirit and scope of the invention. Further, though advantages of the present invention are indicated, it should be appreciated that not every embodiment of the technology described herein will include every described advantage. Some embodiments may not implement any features described as advantageous herein and in some instances one or more of the described features may be implemented to achieve further embodiments. Accordingly, the foregoing description and drawings are by way of example only.

Aspects of the present disclosure may include, but are not limited to:
Aspect 1. A system for implementing entangling gates that operate on two logical qubits, the system comprising: a first quantum oscillator; a second quantum oscillator; a coupling element coupled to the first quantum oscillator and to the second quantum oscillator; an ancilla qubit coupled to the first quantum oscillator; at least one energy source; a readout resonator coupled to the ancilla qubit; and at least one controller configured to: perform an entangling gate between logical states of the first quantum oscillator and the second quantum oscillator by operating the at least one energy source to direct energy to the coupling element and/or to the ancilla qubit one or more times; measure a state of the ancilla qubit measured subsequent to performing the entangling gate; and determine whether the entangling gate produced an error based on the measured state of the ancilla qubit.
Aspect 2. The system of aspect 1, wherein: the coupling element is dispersively coupled to the first quantum oscillator and to the second quantum oscillator; and the ancilla qubit is dispersively coupled to the first quantum oscillator.
Aspect 3. The system of any of aspects 1-2, wherein the coupling element is a transmon qubit, a superconducting nonlinear asymmetric inductive element (SNAIL), or a superconducting quantum interference device (SQUID).
Aspect 4. The system of any of aspects 1-3, wherein operating the at least one energy source to direct energy to the coupling element and/or to the ancilla qubit one or more times comprises operating the at least one energy source to direct microwave tones to the coupling element and/or to the ancilla qubit one or more times.
Aspect 5. The system of any of aspects 1-4, wherein the ancilla qubit is not coupled to the second quantum oscillator.
Aspect 6. The system of any of aspects 1-5, wherein the at least one controller is configured to measure the state of the ancilla qubit subsequent to performing the entangling gate by operating the at least one energy source to direct energy to the readout resonator.
Aspect 7. The system of any of aspects 1-6, wherein the at least one controller is further configured to operate the at least one energy source to arrange the ancilla qubit in a ground state prior to performing the entangling gate.
Aspect 8. The system of any of aspects 1-7, wherein performing the entangling gate between logical states of the first quantum oscillator and the second quantum oscillator comprises operating the at least one energy source to: direct energy to the ancilla qubit to perform a first rotation of the state of the ancilla qubit; direct energy to the coupling element to perform a beamsplitter operation on the first quantum oscillator and the second quantum oscillator; and direct energy to the ancilla qubit to perform a second rotation of the state of the ancilla qubit.
Aspect 9. The system of aspect 8, wherein the ancilla qubit exhibits a ground state |g [symbol] , a first excited state |e [symbol] and a second excited state |f [symbol] , and wherein the first and second rotations of the state of the ancilla qubit are rotations between the ground state |g [symbol] and the second excited state |f [symbol] of the ancilla qubit.
Aspect 10. The system of any of aspects 1-9, wherein performing the entangling gate between logical states of the first quantum oscillator and the second quantum oscillator further comprises operating the at least one energy source to direct energy to the coupling element for a length of time that is half the length of time that would be required to swap excitations of the first and second quantum oscillators.
Aspect 11. The system of any of aspects 1-10, wherein the ancilla qubit is a transmon qubit.
Aspect 12. A system for implementing entangling gates that operate on two dual-rail qubits, the system comprising: a first dual-rail qubit comprising: a first quantum oscillator; a second quantum oscillator; a first coupling element coupled to the first quantum oscillator and to the second quantum oscillator; and an ancilla qubit coupled to the second quantum oscillator; a second dual-rail qubit comprising: a third quantum oscillator; a fourth quantum oscillator; and a second coupling element coupled to the third quantum oscillator and to the fourth quantum oscillator; a third coupling element coupled to the second quantum oscillator and to the third quantum oscillator; at least one energy source; and at least one controller configured to: perform an entangling gate between a dual-rail state of the first dual-rail qubit and a dual-rail state of the second dual-rail qubit by operating the at least one energy source to direct energy to the third coupling element and/or to the ancilla qubit one or more times; measure a state of the ancilla qubit measured subsequent to performing the entangling gate; and determine whether the entangling gate produced an error based on the measured state of the ancilla qubit.
Aspect 13. The system of aspect 12, wherein the at least one controller is further configured to operate the at least one energy source to arrange the first dual-rail qubit in a 0 or 1 logical state by: when the first dual-rail qubit is to be initialized in the 0 logical state, operating the at least one energy source to arrange the first quantum oscillator in a single photon state and the second quantum oscillator in its ground state; or when the first dual-rail qubit is to be initialized in the 1 logical state, operating the at least one energy source to arrange the first quantum oscillator in its ground state and the second quantum oscillator in a single photon state.
Aspect 14. The system of aspect 13, wherein the at least one controller is further configured to operate the at least one energy source to arrange the second dual-rail qubit in a 0 or 1 logical state by: when the second dual-rail qubit is to be initialized in the 0 logical state, operating the at least one energy source to arrange the third quantum oscillator in a single photon state and the fourth quantum oscillator in its ground state; or when the second dual-rail qubit is to be initialized in the 1 logical state, operating the at least one energy source to arrange the third quantum oscillator in its ground state and the fourth quantum oscillator in a single photon state.
Aspect 15. The system of any of aspects 12-14, wherein each of the first coupling element, second coupling element and third coupling element is one of: a transmon qubit, a superconducting nonlinear asymmetric inductive element (SNAIL), or a superconducting quantum interference device (SQUID).
Aspect 16. The system of any of aspects 12-15, wherein operating the at least one energy source to direct energy to the third coupling element and/or to the ancilla qubit one or more times comprises operating the at least one energy source to direct microwave tones to the third coupling element and/or to the ancilla qubit one or more times.
Aspect 17. The system of any of aspects 12-16, wherein the ancilla qubit is not coupled to the first quantum oscillator.
Aspect 18. The system of any of aspects 12-17, wherein the at least one controller is configured to measure the state of the ancilla qubit subsequent to performing the entangling gate by operating the at least one energy source to direct energy to a readout resonator coupled to the ancilla qubit.
Aspect 19. The system of any of aspects 12-18, wherein the ancilla qubit is a transmon qubit.

The above-described embodiments of the technology described herein can be implemented in any of numerous ways. For example, the controller of any of the embodiments, including controller 106 shown in FIG. 1, may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component, including commercially available integrated circuit components known in the art by names such as CPU chips, GPU chips, microprocessor, microcontroller, or co-processor. Alternatively, a processor may be implemented in custom circuitry, such as an ASIC, or semi-custom circuitry resulting from configuring a programmable logic device. As yet a further alternative, a processor may be a portion of a larger circuit or semiconductor device, whether commercially available, semi-custom or custom. As a specific example, some commercially available microprocessors have multiple cores such that one or a subset of those cores may constitute a processor. Though, a processor may be implemented using circuitry in any suitable format.

Various aspects of the present invention may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

1. A system for implementing entangling gates that operate on two logical qubits, the system comprising:
a first quantum oscillator;
a second quantum oscillator;
a coupling element coupled to the first quantum oscillator and to the second quantum oscillator;
an ancilla qubit coupled to the first quantum oscillator;
at least one energy source;
a readout resonator coupled to the ancilla qubit; and
at least one controller configured to:
perform an entangling gate between logical states of the first quantum oscillator and the second quantum oscillator by operating the at least one energy source to direct energy to the coupling element and/or to the ancilla qubit one or more times;
measure a state of the ancilla qubit measured subsequent to performing the entangling gate; and
determine whether the entangling gate produced an error based on the measured state of the ancilla qubit.

2. The system of claim 1, wherein:
the coupling element is dispersively coupled to the first quantum oscillator and to the second quantum oscillator; and
the ancilla qubit is dispersively coupled to the first quantum oscillator.

3. The system of claim 1, wherein the coupling element is a transmon qubit, a superconducting nonlinear asymmetric inductive element (SNAIL), or a superconducting quantum interference device (SQUID).

4. The system of claim 1, wherein operating the at least one energy source to direct energy to the coupling element and/or to the ancilla qubit one or more times comprises operating the at least one energy source to direct microwave tones to the coupling element and/or to the ancilla qubit one or more times.

5. The system of claim 1, wherein the ancilla qubit is not coupled to the second quantum oscillator.

6. The system of claim 1, wherein the at least one controller is configured to measure the state of the ancilla qubit subsequent to performing the entangling gate by operating the at least one energy source to direct energy to the readout resonator.

7. The system of claim 1, wherein the at least one controller is further configured to operate the at least one energy source to arrange the ancilla qubit in a ground state prior to performing the entangling gate.

8. The system of claim 1, wherein performing the entangling gate between logical states of the first quantum oscillator and the second quantum oscillator comprises operating the at least one energy source to:
direct energy to the ancilla qubit to perform a first rotation of the state of the ancilla qubit;
direct energy to the coupling element to perform a beamsplitter operation on the first quantum oscillator and the second quantum oscillator; and
direct energy to the ancilla qubit to perform a second rotation of the state of the ancilla qubit.

9. The system of claim 8, wherein the ancilla qubit exhibits a ground state |g [symbol] , a first excited state |e [symbol] and a second excited state |f [symbol] , and wherein the first and second rotations of the state of the ancilla qubit are rotations between the ground state |g [symbol] and the second excited state |f [symbol] of the ancilla qubit.

10. The system of claim 1, wherein performing the entangling gate between logical states of the first quantum oscillator and the second quantum oscillator further comprises operating the at least one energy source to direct energy to the coupling element for a length of time that is half the length of time that would be required to swap excitations of the first and second quantum oscillators.

11. The system of claim 1, wherein the ancilla qubit is a transmon qubit.

12. A system for implementing entangling gates that operate on two dual-rail qubits, the system comprising:
a first dual-rail qubit comprising:
a first quantum oscillator;
a second quantum oscillator;
a first coupling element coupled to the first quantum oscillator and to the second quantum oscillator; and
an ancilla qubit coupled to the second quantum oscillator;
a second dual-rail qubit comprising:
a third quantum oscillator;
a fourth quantum oscillator; and
a second coupling element coupled to the third quantum oscillator and to the fourth quantum oscillator;
a third coupling element coupled to the second quantum oscillator and to the third quantum oscillator;
at least one energy source; and
at least one controller configured to:
perform an entangling gate between a dual-rail state of the first dual-rail qubit and a dual-rail state of the second dual-rail qubit by operating the at least one energy source to direct energy to the third coupling element and/or to the ancilla qubit one or more times;
measure a state of the ancilla qubit measured subsequent to performing the entangling gate; and
determine whether the entangling gate produced an error based on the measured state of the ancilla qubit.

13. The system of claim 12, wherein the at least one controller is further configured to operate the at least one energy source to arrange the first dual-rail qubit in a 0 or 1 logical state by:
when the first dual-rail qubit is to be initialized in the 0 logical state, operating the at least one energy source to arrange the first quantum oscillator in a single photon state and the second quantum oscillator in its ground state; or
when the first dual-rail qubit is to be initialized in the 1 logical state, operating the at least one energy source to arrange the first quantum oscillator in its ground state and the second quantum oscillator in a single photon state.

14. The system of claim 13, wherein the at least one controller is further configured to operate the at least one energy source to arrange the second dual-rail qubit in a 0 or 1 logical state by:
when the second dual-rail qubit is to be initialized in the 0 logical state, operating the at least one energy source to arrange the third quantum oscillator in a single photon state and the fourth quantum oscillator in its ground state; or
when the second dual-rail qubit is to be initialized in the 1 logical state, operating the at least one energy source to arrange the third quantum oscillator in its ground state and the fourth quantum oscillator in a single photon state.

15. The system of claim 12, wherein each of the first coupling element, second coupling element and third coupling element is one of: a transmon qubit, a superconducting nonlinear asymmetric inductive element (SNAIL), or a superconducting quantum interference device (SQUID).

16. The system of claim 12, wherein operating the at least one energy source to direct energy to the third coupling element and/or to the ancilla qubit one or more times comprises operating the at least one energy source to direct microwave tones to the third coupling element and/or to the ancilla qubit one or more times.

17. The system of claim 12, wherein the ancilla qubit is not coupled to the first quantum oscillator.

18. The system of claim 12, wherein the at least one controller is configured to measure the state of the ancilla qubit subsequent to performing the entangling gate by operating the at least one energy source to direct energy to a readout resonator coupled to the ancilla qubit.

19. The system of claim 12, wherein the ancilla qubit is a transmon qubit.
